(19) United States
(12) Patent Application Publication
(10) Pub. No.: US 2011/0180855 A1
(43) Pub. Date: Jul. 28, 2011

(54) NON-DIRECT BOND COPPER ISOLATED LATERAL WIDE BAND GAP SEMICONDUCTOR DEVICE

(75) Inventors: GEORGE R. WOODY, REDONDO BEACH, CA (US); TERENCE G. WARD, REDONDO BEACH, CA (US); KARIM BOUTROS, MOORPARK, CA (US); BRIAN HUGHES, CALABASAS, CA (US)

(73) Assignee: GM GLOBAL TECHNOLOGY OPERATIONS, INC., DETROIT, MI (US)

(21) Appl. No.: 12/695,409

(22) Filed: Jan. 28, 2010

(51) Int. Cl. H01L 27/06

(52) U.S. Cl. 257/213; 257/E27.016

(57) ABSTRACT

Non-direct bond copper isolated lateral wide band gap semiconductor devices are provided. One semiconductor device includes a heat sink, a buffer layer directly overlying the heat sink, and an epitaxial layer formed of a group-III nitride overlying the buffer layer. Another semiconductor device includes a heat sink, a substrate directly overlying the heat sink, a buffer layer directly overlying the substrate, and an epitaxial layer formed of a group-III nitride overlying the buffer layer. Being formed of a group-III nitride enables the various epitaxial layers to be electrically isolated from their respective heat sinks.

### FIELD OF THE INVENTION

The present invention generally relates to semiconductor devices, and more particularly relates to non-direct bond copper substrates or similar isolated lateral wide band gap semiconductor devices.

### BACKGROUND OF THE INVENTION

Controlling the amount of heat a semiconductor device generates is one of the design challenges for packaging power electronics. With reference to FIG. 1, a contemporary semiconductor device 100 typically has a silicon die 110 consisting of a vertically-constructed switch 1110 (e.g., a switch having a gate 1112 and a source 1114 on a top layer of the device and a drain 1116 located on a layer beneath the top layer) and a separate silicon die 111 consisting of a diode 1120 overlying a heat sink 120. To isolate silicon dies 110 and 111 from heat sink 120, semiconductor device 100 includes a direct bond copper (DBC) structure 130 (or another similar structure) separating silicon dies 110 and 111 from heat sink 120. Silicon dies 110 and 111 are attached to DBC 130 via soldering, sintering, thermal grease, or other similar techniques at interface 112. Likewise, DBC 130 is attached to heat sink 120 via soldering, sintering, thermal grease, or other similar techniques at interface 113.

DBC structure 130 includes a first copper layer 1310, a second copper layer 1320, and a ceramic isolation layer 1330. First copper layer 1310 overlies heat sink 120, while second copper underlies silicon die 110. Ceramic insulator layer 1330 may be formed of aluminum oxide, aluminum nitride, or silicon nitride, and separates first copper layer 1310 and second copper layer 1320. While semiconductor device 100 functions properly, the inclusion of DBC structure 130 to electrically isolate silicon dies 110 and 111 from heat sink 120 unnecessarily increases the junction temperature of semiconductor device 100 during operation, which may affect the performance and/or life span of semiconductor device 100. Furthermore, the inclusion of the attachment layers at interfaces 112 and 113 increase the amount of thermal resistance in semiconductor device 100.

Accordingly, it is desirable to provide semiconductor devices that do not require a DBC structure, and yet maintain electrical isolation between an epitaxial layer and a heat sink. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Various embodiments provide non-direct bond copper isolated lateral wide band gap semiconductor devices and power modules. One device comprises a heat sink, a buffer layer directly overlying the heat sink, and an epitaxial layer overlying the buffer layer. In one embodiment, the epitaxial layer is formed of a group-III nitride such that the epitaxial layer is electrically isolated from the heat sink.

Another device comprises a heat sink, a substrate directly overlying the heat sink, a buffer layer directly overlying the substrate, and an epitaxial layer overlying the buffer layer. The epitaxial layer, in one embodiment, is formed of a group-III nitride such that the epitaxial layer is electrically isolated from the heat sink.

### BRIEF DESCRIPTION OF THE DRAWINGS

The present invention will hereinafter be described in conjunction with the following drawing figures, wherein like numerals denote like elements, and

FIG. 1 is a diagram illustrating a prior art semiconductor device including a direct bond copper (DBC) type structure separating a silicon die from a heat sink;

FIG. 2 is a diagram illustrating one embodiment of an isolated non-DBC type semiconductor device; and

FIG. 3 is a diagram illustrating another embodiment of an isolated non-DBC type semiconductor device.

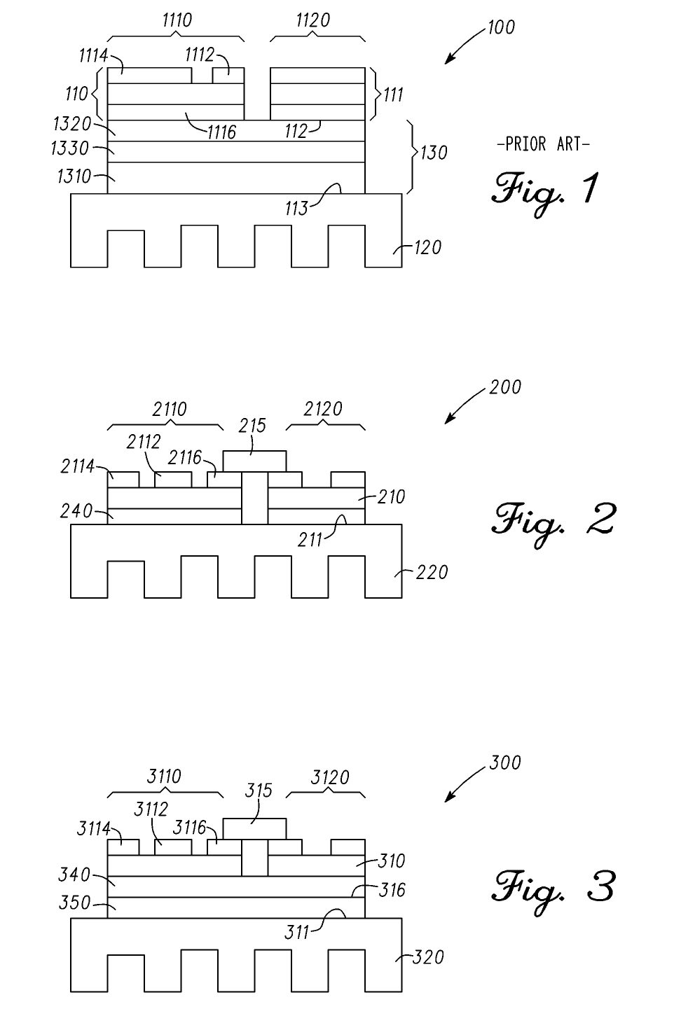

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

FIG. 2 is a diagram of one embodiment of an isolated non-DBC type semiconductor device 200. At least in the illustrated embodiment, semiconductor device 200 comprises an epitaxial layer 210 directly overlying a buffer layer 240, which is directly coupled to a heat sink 220. In one exemplary embodiment, the semiconductor device 200 comprises a power module having a heat sink 200 long with a semiconductor component that is attached to the heat sink.

In the depicted embodiment, epitaxial layer 210 forms a semiconductor dies and comprises a horizontally-constructed switch 2110 and a diode 2120 horizontally coupled to switch 2110 via one or more electrodes 215 (or one or more wire bonds). In certain embodiments, metallization can be utilized instead of wire bonds. In one embodiment, epitaxial layer 210 is a semiconductor die formed of a group-III nitride. That is, epitaxial layer 210 may be a gallium nitride (GaN) die, a boron nitride (BN) die, an aluminum nitride (AlN) die, an indium nitride (InN) die, or a thallium nitride (TlN) die. In another embodiment, epitaxial layer 210 is a semiconductor die formed of silicon, silicon carbide, and the like semiconductor materials.

Switch 2110 comprises a gate 2112, a source 2114, and a drain 2116. As illustrated in FIG. 2, gate 2112, source 2114, and drain 2116 are disposed horizontally on a top surface of epitaxial layer 210 with respect to one another.

Buffer layer 240 may be formed of any insulating material known in the art or developed in the future. Buffer layer 240 is directly coupled to heat sink 220 via, for example, solder, sintering, thermal grease, or other similar technique at interface 211.

Heat sink 220 may be any material, device, or object known in the art or developed in the future capable of absorbing and/or dissipating heat from epitaxial layer 210. Examples of heat sink 220 include, but are not limited to, aluminum, copper, ceramic, aluminum silicon carbide, a heat pipe, a vapor chamber, and the like material, device, or object.

In various embodiments, semiconductor device 200 forms at least a portion of a power module. Examples of such a power module include, but are not limited to, a semiconductor switch wherein switch 2110 is coupled antiparallel with diode 2120, a semiconductor switch wherein switch 2110 is coupled parallel with diode 2120, an inverter leg in a half bridge configuration, an inverter leg in a three phase inverter, a converter, and/or the like power modules.

The group-III nitride epitaxial layer 210 in semiconductor device 200 is electrically isolated from heat sink 220. That is, because epitaxial layer 210 is electrically isolated from heat sink 220 via buffer layer 240, semiconductor device 200 does not require a direct bond copper (DBC) type structure, which enables semiconductor device 200 to operate at a lower junction temperature than contemporary semiconductor devices (e.g., semiconductor device 100). Specifically, because semiconductor device 200 does not require a DBC type structure, the junction temperature of semiconductor device 200 is approximately 28° C. less than the junction temperature of semiconductor device 100 during operation. Alternatively, semiconductor device 200 can operate at the same junction temperature as contemporary semiconductor devices, but at a higher power density.

FIG. 3 is a diagram of another embodiment of an isolated non-DBC type semiconductor device 300. At least in the illustrated embodiment, semiconductor device 300 comprises an epitaxial layer 310 directly overlying a buffer layer 340, and a substrate 350 directly underlying buffer layer 340 and directly coupled to a heat sink 320.

Epitaxial layer 310 forms a semiconductor die and comprises a horizontally-constructed switch 3110 and a diode 3120 horizontally coupled to switch 3110 via one or more electrodes 315 (or one or more wire bonds). In one embodiment, epitaxial layer 310 is a semiconductor die formed of a group-III nitride. That is, epitaxial layer 310 may be a gallium nitride (GaN) die, a boron nitride (BN) die, an aluminum nitride (AlN) die, an indium nitride (InN) die, or a thallium nitride (TlN) die.

Switch 3110 comprises a gate 3112, a source 3114, and a drain 3116. As illustrated in FIG. 3, gate 3112, source 3114, and drain 3116 are disposed horizontally on a top surface of epitaxial layer 310 with respect to one another.

Buffer layer 340 may be formed of any insulating material known in the art or developed in the future. Buffer layer 340 is directly coupled to substrate 350 via, for example, solder, sintering, thermal grease, or other similar technique at interface 316.

Substrate 350 may be formed of any substrate material known in the art or developed in the future. Examples of substrate 350 include, but are not limited to, silicon, sapphire, silicon carbon, and the like substrate materials. Substrate 350 is configured to provide mechanical support for semiconductor device 300, but should be as thin as possible to reduce the thermal resistance of substrate 350.

Heat sink 320 may be any material, device, or object known in the art or developed in the future capable of absorbing and/or dissipating heat from epitaxial layer 310. Examples of heat sink 320 include, but are not limited to, aluminum, copper, ceramic, aluminum silicon carbide, a heat pipe, a vapor chamber, and the like material, device, or object.

In various embodiments, semiconductor device 300 forms at least a portion of a power module. Examples of such a power module include, but are not limited to, a semiconductor switch wherein switch 3110 is coupled antiparallel with diode 3120, a semiconductor switch wherein switch 3110 is coupled parallel with diode 3120, an inverter leg in a half bridge configuration, an inverter leg in a three phase inverter, a converter, and/or the like power modules.

The group-III nitride epitaxial layer 310 in semiconductor device 300 is electrically isolated from heat sink 320. That is, because epitaxial layer 310 is electrically isolated from heat sink 320 via buffer layer 340, semiconductor device 200 does not require a direct bond copper (DBC) type structure, which enables semiconductor device 300 to operate at a lower junction temperature than contemporary semiconductor devices (e.g., semiconductor device 100). Specifically, because semiconductor device 300 does not require a DBC type structure, the junction temperature of semiconductor device 300 is approximately 20° C. less than the junction temperature of semiconductor device 100 during operation. Alternatively, semiconductor device 300 can operate at the same junction temperature as contemporary semiconductor devices, but at a higher power density.

Though the various embodiments discussed herein have been made with reference to a heterostructure field-effect transistor (HFET), the invention is not limited to HFET devices. That is, semiconductor devices 200 and 300 may be implemented as any device that has a horizontally-constructed gate, source, and drain on a top surface.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A device, comprising:
a heat sink;
a buffer layer directly overlying the heat sink; and
an epitaxial layer formed of a group-III nitride overlying the buffer layer.

2. The device of claim 1, wherein the buffer layer is electrically isolated from the heat sink.

3. The device of claim 1, wherein the epitaxial layer comprises a laterally-constructed diode.

4. The device of claim 1, wherein the epitaxial layer comprises a laterally-constructed switch.

5. The device of claim 1, wherein the epitaxial layer comprises:
a laterally-constructed diode; and
a laterally-constructed switch coupled to the laterally-constructed diode.

6. The device of claim 5, further comprising an electrode, at least one wire bond, or integrated circuit metallization connecting the laterally-constructed switch and the laterally-constructed diode.

7. The device of claim 5, wherein the laterally-constructed diode and the laterally-constructed switch are electrically isolated from the heat sink.

8. The device of claim 4, wherein the laterally-constructed switch comprises a gate terminal, a source terminal, and a drain terminal.

9. The device of claim 8, wherein:
the epitaxial layer comprises a top side, and
the gate terminal, the source terminal, and the drain terminal are each located on the top side.

10. The device of claim 1, wherein the device forms at least a portion of a power module.

11. A device, comprising:
a heat sink;
a substrate directly overlying the heat sink;
a buffer layer directly overlying the substrate; and
an epitaxial layer formed of a group-III nitride overlying the buffer layer.

12. The device of claim 11, wherein the buffer layer is electrically isolated from the heat sink.

13. The device of claim 11, wherein the epitaxial layer comprises a laterally-constructed diode.

14. The device of claim 11, wherein the epitaxial layer comprises a laterally-constructed switch.

15. The device of claim 1, wherein the epitaxial layer comprises:
a laterally-constructed diode; and
a laterally-constructed switch coupled to the laterally-constructed diode.

16. The device of claim 15, further comprising an electrode, at least one wire bond, or integrated circuit metallization connecting the laterally-constructed switch and the laterally-constructed diode.

17. The device of claim 15, wherein the laterally-constructed diode and the laterally-constructed switch are electrically isolated from the heat sink.

18. The device of claim 14, wherein the laterally-constructed switch comprises a gate terminal, a source terminal, and a drain terminal.

19. The device of claim 18, wherein:
the epitaxial layer comprises a top side, and
the gate terminal, the source terminal, and the drain terminal are each located on the top side.

20. The device of claim 11, wherein the device forms at least a portion of a power module.
